(19) United States
(12) Patent Application Publication
(10) Pub. No.: US 2026/0143621 A1
(43) Pub. Date: May 21, 2026

(54) Server System Component Array Connection System

(71) Applicant: Dell Products L.P., Round Rock, TX (US)

(72) Inventors: Walter R. Carver, Round Rock, TX (US); Eduardo Escamilla, Round Rock, TX (US)

(21) Appl. No.: 18/951,769

(22) Filed: Nov. 19, 2024

(51) Int. Cl. H05K 7/14

(52) U.S. Cl. CPC H05K 7/1492

(57) ABSTRACT

A direct connect component connection system for use with an information handling system. The direct connect component connection system for an information handling system, includes a baseboard component, the baseboard component comprising a printed circuit board and a plurality of blind mate connectors positioned along an edge of the printed circuit board and a plurality of component interface components, each of the plurality of component interface components comprising a respective component interface blind mate connector, each respective component interface blind mate connector being positioned to directly mate with a blind mate connector of the baseboard component.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a server system with a direct connect component connection system.

In one embodiment, the invention relates to a direct connect component connection system for an information handling system comprising: a baseboard component, the baseboard component comprising a printed circuit board and a plurality of blind mate connectors positioned along an edge of the printed circuit board; and; a plurality of component interface components, each of the plurality of component interface components comprising a respective component interface blind mate connector, each respective component interface blind mate connector being positioned to directly mate with a blind mate connector of the baseboard component.

In another embodiment, the invention relates to a component array system for use in an information handling system comprising: an array of components, the array of components comprising a plurality of components; and, a direct connect component connection system for an information handling system comprising: a baseboard component, the baseboard component comprising a printed circuit board and a plurality of blind mate connectors positioned along an edge of the printed circuit board; and; a plurality of component interface components, each of the plurality of component interface components comprising a respective component interface blind mate connector, each respective component interface blind mate connector being positioned to directly mate with a blind mate connector of the baseboard component.

In another embodiment, the invention relates to a system comprising: a chassis; a processor contained within the chassis; a data bus coupled to the processor; an array of components, the array of components comprising a plurality of components; and, a direct connect component connection system for directly connecting with the array of components, the direct connect component connection system comprising: a baseboard component, the baseboard component comprising a printed circuit board and a plurality of blind mate connectors positioned along an edge of the printed circuit board; and; a plurality of component interface components, each of the plurality of component interface components comprising a respective component interface blind mate connector, each respective component interface blind mate connector being positioned to directly mate with a blind mate connector of the baseboard component.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIGS. 4A and 4B, generally referred to as FIG. 4, show views of a component array and a component connection system.

FIG. 5 shows a perspective view of a component used with a component connection system.

### DETAILED DESCRIPTION

Various aspects of the present disclosure include an appreciation that it is known to provide information handling systems with a plurality of components. Various aspects of the present disclosure include an appreciation that graphics processing unit (GPU) modules are one example of a component that is included within an information handling system. Various aspects of the present disclosure include an appreciation that it may be desirable to provide an information handling system with an array of components. Various aspects of the present disclosure include an appreciation that it may be desirable to install an array of GPU modules within an information handling system.

Various aspects of the present disclosure include an appreciation that GPU modules are often configured to conform to form factor standards. Various aspects of the present disclosure include an appreciation that the card electromechanical (CEM) form factor standard is one such form factor standard.

Various aspects of the present disclosure include an appreciation that with certain CEM GPU module configurations, it can be advantageous to provide point-to-point connections from a baseboard component, which functions as a processor to PCIe switch, to each of the GPU modules. Various aspects of the present disclosure include an appreciation that these point-to-point connections are often between a peripheral component interconnect express (PCIe) type connector and the GPU module. Various aspects of the present disclosure include an appreciation that the GPU module is often configured to include a peripheral component interconnect express (PCIe) CEM card edge connector. Various aspects of the present disclosure include an appreciation that connections between the PCIe type connector of the baseboard component and the PCIe CEM card edge connection are often configured with point-to-point PCIe cabling.

Various aspects of the present disclosure include an appreciation that this point-to-point PCIe cabling can often cause one or more issues. For example, the high speed cables needed to provide the connections are expensive, can be time consuming to install and route, can easily become disconnected resulting in reseating of the connection, can make servicing of a GPU module challenging as adjacent cables can interfere with access to the GPU module, can cause adjacent cables to be inadvertently disconnected during servicing and can block or restrict cooling airflow. Additionally, overlapping the baseboard component with the GPU module array is impractical as this configuration would likely necessitate all cables to be disconnected to remove the baseboard component to provide access to any GPU module of the GPU module array. Because it is difficult to overlap the baseboard component with e GPU module array, this GPU array and baseboard component configuration increases the depth required to service the GPU array.

Various aspects of the present disclosure include an appreciation that with certain CEM GPU module configurations, it can be advantageous to provide point-to-point connections between multiple GPU modules contained in the system. Various aspects of the present disclosure include an appreciation that the point-to-point GPU module to GPU module connections may conform to certain GPU interconnect specifications such as the VNLink interconnection specification or the UALink specification.

Various aspects of the present disclosure include an appreciation that the point-to-point GPU module to GPU module connections also can often cause one or more issues. For example, the high speed cables needed to provide the connections are expensive, can be time consuming to install and route, can easily become disconnected resulting in reseating of the connection, can make servicing of a GPU module challenging as adjacent cables can interfere with access to the GPU module, can cause adjacent cables to be inadvertently disconnected during servicing and can block or restrict cooling airflow.

A system and method are disclosed for providing an information handling system with a GPU module array system which includes a direct connect component connection system and a GPU module array. In certain embodiments, the direct connect component connection system includes a direct connect baseboard component. In certain embodiments, the direct connect baseboard component includes a plurality of blind mate connectors. In certain embodiments, the plurality of blind mate connectors are positioned along an edge of a printed circuit board of the direct connect baseboard component. In certain embodiments, the plurality of blind mate connectors includes respective PCIe type blind mate connectors.

In certain embodiments, the direct connect component connection system includes a plurality of GPU module interface component blind mate connectors. In certain embodiments, the plurality of blind mate connectors of the baseboard component is positioned to mate with the plurality of GPU module interface component blind mate connectors. In certain embodiments, the plurality of GPU module interface component blind mate connectors includes respective PCIe type blind mate connectors. In certain embodiments, each GPU module interface component includes a CEM type PCIe interface printed circuit board. In certain embodiments, the direct connect component connection system eliminates the need for point-to-point PCIe cables to connect a baseboard component with a GPU module array.

In certain embodiments, the direct connect component connection system is configured to allow the baseboard component to connect directly with the PCIe interface printed circuit boards of each of the plurality of GPU modules of the GPU module array. In certain embodiments, by connecting directly with the PCIe interface printed circuit boards, the baseboard component physically overlaps with a portion of the GPU module array. In certain embodiments, by so overlapping, the overall depth of the combination of the direct connect component connection system and the GPU module array is reduced.

In certain embodiments, when servicing the GPU module array, the direct connect baseboard component is simply unplugged from the plurality of GPU module interface component blind mate connectors. In certain embodiments, by so unplugging the direct connect baseboard component, all of the GPU modules of the GPU module array are accessible for servicing. In certain embodiments, when servicing of the GPU module array is complete, the direct connect baseboard component is simply re-plugged into the plurality of GPU module interface component blind mate connectors.

Such a direct connect component connection system advantageously provides a single planar direct connect baseboard module which connects to a plurality of GPU module interface component blind mate connectors. Such a direct connect component connection system advantageously reduces part counts and complexity. Such a direct connect component connection system advantageously lowers the cost of the GPU module array system. Such a direct connect component connection system advantageously simplifies factory assembly of the GPU module array system. Such a direct connect component connection system advantageously simplifies serviceability of the GPU module array system. Such a direct connect component connection system advantageously improves reliability of the GPU module array system. Such a direct connect component connection system advantageously reduces the overall depth of the combination of the GPU module array system.

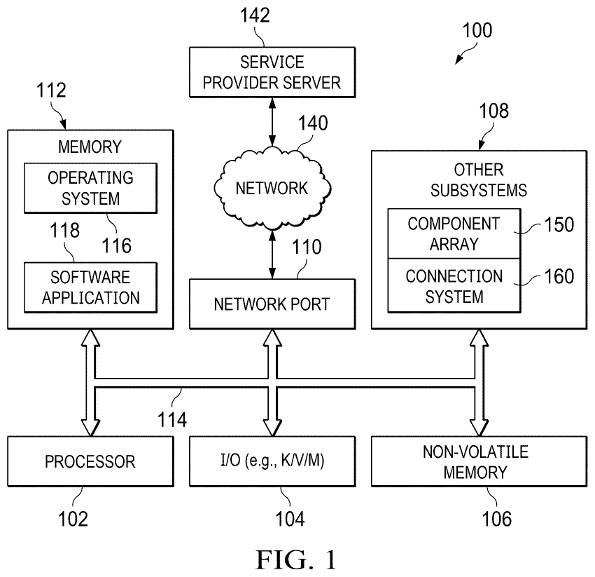

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include a component array 150 and an array connection system 160. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the component array 150 and the connection system 160 provide a component array system. In certain embodiments, the component array 150 includes a GPU module array. In certain embodiments, the connection system 160 includes a direct connect component connection system. In certain embodiments, a GPU module array system includes a direct connect component connection system and a GPU module array. In certain embodiments, the direct connect component connection system includes a direct connect baseboard component. In certain embodiments, the direct connect baseboard component includes a plurality of blind mate connectors. In certain embodiments, the plurality of blind mate connectors are positioned along an edge of a printed circuit board of the direct connect baseboard component. In certain embodiments, the plurality of blind mate connectors includes respective PCIe type blind mate connectors. In certain embodiments, the direct connect baseboard component includes a CPU/PCIe switch for communicating between a processor and a plurality of PCIe components.

In certain embodiments, the direct connect component connection system includes a plurality of GPU module interface component blind mate connectors. In certain embodiments, the plurality of blind mate connectors of the baseboard component are positioned to mate with the plurality of GPU module interface component blind mate connectors. In certain embodiments, the plurality of GPU module interface component blind mate connectors includes respective PCIe type blind mate connectors. In certain embodiments, each GPU module interface component includes a CEM type PCIe interface printed circuit board. In certain embodiments, the direct connect component connection system eliminates the need for point-to-point PCIe cables to connect a baseboard component with a GPU module array.

In certain embodiments, the direct connect component connection system is configured to allow the baseboard component to connect directly with the PCIe interface printed circuit boards of each of the plurality of GPU modules of the GPU module array. In certain embodiments, by connecting directly with the PCIe interface printed circuit boards, the baseboard component physically overlaps with a portion of the GPU module array. In certain embodiments, by so overlapping, the overall depth of the combination of the direct connect component connection system and the GPU module array is reduced.

In certain embodiments, when servicing the GPU module array, the direct connect baseboard component is simply unplugged from the plurality of GPU module interface component blind mate connectors. In certain embodiments, by so unplugging the direct connect baseboard component, all of the GPU modules of the GPU module array are accessible for servicing. In certain embodiments, when servicing of the GPU module array is complete, the direct connect baseboard component is simply re-plugged into the plurality of GPU module interface component blind mate connectors.

Such a direct connect component connection system advantageously provides a single planar direct connect baseboard module which connects to a plurality of GPU module interface component blind mate connectors. Such a direct connect component connection system advantageously reduces part counts and complexity. Such a direct connect component connection system advantageously lowers the cost of the GPU module array system. Such a direct connect component connection system advantageously simplifies factory assembly of the GPU module array system. Such a direct connect component connection system advantageously simplifies serviceability of the GPU module array system. Such a direct connect component connection system advantageously improves reliability of the GPU module array system. Such a direct connect component connection system advantageously reduces the overall depth of the combination of the GPU module array system.

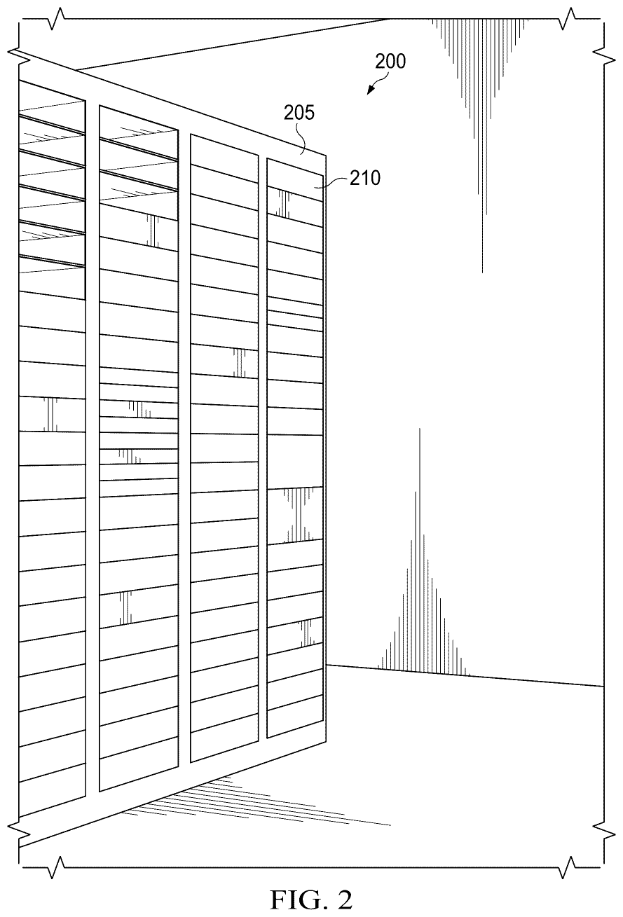

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100, as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1 U rack unit, a 2 U rack unit, and a 4 U rack unit. In general, a 1 U rack unit is substantially (i.e., +/−20%) 1.75″ high, a 2 U rack unit is substantially (i.e., +/−20%) 3.5″ high, and a 4 U rack height is substantially (i.e., +/−20%) 7.0″ high.

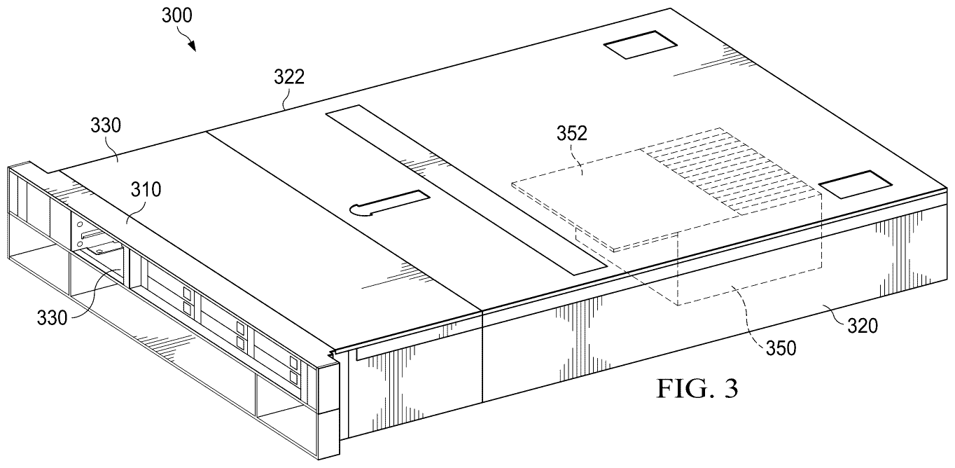

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300.

In certain embodiments, the blade type information handing system 300 includes a component array 350 and a component connection system 352. In certain embodiments, the component array 350 corresponds to component array 150. In certain embodiments, the component connection system 352 corresponds to connection system 160.

In certain embodiments, the component array 350 and the connection system 352 provide a component array system. In certain embodiments, the component array 350 includes a GPU module array. In certain embodiments, the connection system 352 includes a direct connect component connection system. In certain embodiments, a GPU module array system includes a direct connect component connection system and a GPU module array. In certain embodiments, the direct connect component connection system includes a direct connect baseboard component. In certain embodiments, the direct connect baseboard component includes a plurality of blind mate connectors. In certain embodiments, the plurality of blind mate connectors are positioned along an edge of a printed circuit board of the direct connect baseboard component. In certain embodiments, the plurality of blind mate connectors includes respective PCIe type blind mate connectors.

In certain embodiments, the direct connect component connection system includes a plurality of GPU module interface component blind mate connectors. In certain embodiments, the plurality of blind mate connectors of the baseboard component are positioned to mate with the plurality of GPU module interface component blind mate connectors. In certain embodiments, the plurality of GPU module interface component blind mate connectors includes respective PCIe type blind mate connectors. In certain embodiments, each GPU module interface component includes a CEM type PCIe interface printed circuit board. In certain embodiments, the direct connect component connection system eliminates the need for point-to-point PCIe cables to connect a baseboard component with a GPU module array.

In certain embodiments, the direct connect component connection system is configured to allow the baseboard component to connect directly with the PCIe interface printed circuit boards of each of the plurality of GPU modules of the GPU module array. In certain embodiments, by connecting directly with the PCIe interface printed circuit boards, the baseboard component physically overlaps with a portion of the GPU module array. In certain embodiments, by so overlapping, the overall depth of the combination of the direct connect component connection system and the GPU module array is reduced.

In certain embodiments, when servicing the GPU module array, the direct connect baseboard component is simply unplugged from the plurality of GPU module interface component blind mate connectors. In certain embodiments, by so unplugging the direct connect baseboard component, all of the GPU modules of the GPU module array are accessible for servicing. In certain embodiments, when servicing of the GPU module array is complete, the direct connect baseboard component is simply re-plugged into the plurality of GPU module interface component blind mate connectors.

Such a direct connect component connection system advantageously provides a single planar direct connect baseboard module which connects to a plurality of GPU module interface component blind mate connectors. Such a direct connect component connection system advantageously reduces part counts and complexity. Such a direct connect component connection system advantageously lowers the cost of the GPU module array system. Such a direct connect component connection system advantageously simplifies factory assembly of the GPU module array system. Such a direct connect component connection system advantageously simplifies serviceability of the GPU module array system. Such a direct connect component connection system advantageously improves reliability of the GPU module array system. Such a direct connect component connection system advantageously reduces the overall depth of the combination of the GPU module array system.

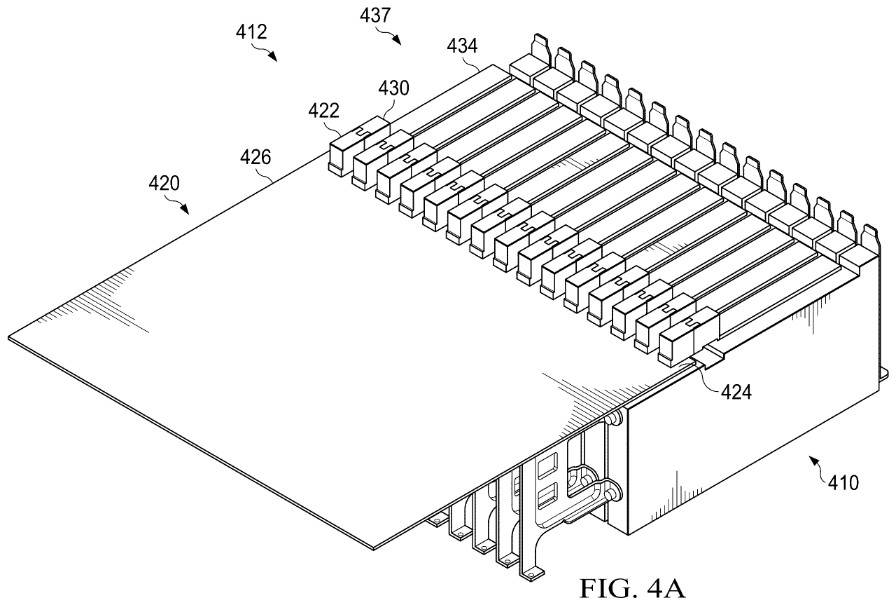

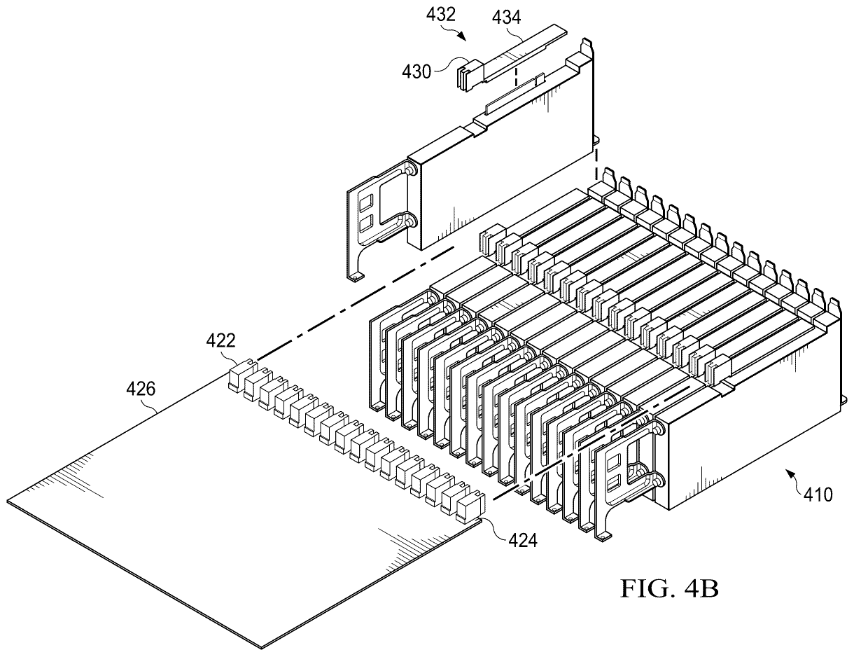

FIGS. 4A and 4B, generally referred to as FIG. 4, show views of a component array and a component connection system. More specifically, FIG. 4A shows a perspective view of a component array system 400. FIG. 4B shows a partially exploded view of a component array system 400. In certain embodiments, the component array system 400 includes a component array 410 and a connection system 412, providing a component array system. In certain embodiments, the component array 410 corresponds to component array 150. In certain embodiments, the component connection system 412 corresponds to connection system 160. As used herein, an array broadly refers to a plurality of information handling system components which are physically arranged substantially (i.e., +/−20%) parallel with each other. In certain embodiments, the component array 410 includes a GPU module array. In certain embodiments, the connection system 412 includes a direct connect component connection system. In certain embodiments, a GPU module array system includes a direct connect component connection system and a GPU module array. In certain embodiments, the GPU module array includes a plurality of GPU modules mounted in an inverted CEM orientation.

In certain embodiments, the direct connect component connection system includes a direct connect baseboard component 420. In certain embodiments, the direct connect baseboard component includes a plurality of blind mate connectors 422. In certain embodiments, the plurality of blind mate connectors 422 are positioned along an edge 424 of a printed circuit board 426 of the direct connect baseboard component. In certain embodiments, the plurality of blind mate connectors includes respective PCIe type blind mate connectors. In certain embodiments, the plurality of blind made connections 422 are substantially evenly distributed across the edge 424 of the printed circuit board 426. In certain embodiments, the direct connect baseboard component 420 includes a CPU/PCIe switch for communicating between a processor and a plurality of PCIe components. In certain embodiments, the printed circuit board 426 includes circuitry for performing a CPU/PCIe switch function.

In certain embodiments, the direct connect component connection system 412 includes a plurality of component interface components 432 where each of the plurality of component interface components 432 include a respective component interface blind mate connector 430. In certain embodiments, each respective component interface blind mate connector 432 is positioned to directly mate with a blind mate connector 422 of the baseboard component. As used herein, directly mating broadly refers to an electrical and physical connection between two connectors within the need for any intermediary connection components such as intermediary cables. In certain embodiments, each component interface component 432 includes a PCIe interface component, where the PCIe interface component provides a PCIe interface between a component of the component array 410 and the baseboard component 420.

In certain embodiments, the plurality of component interface components includes a plurality of GPU module interface components. In certain embodiments, a plurality of GPU module interface component blind mate connectors 430 of a GPU module interface component 432. In certain embodiments, the plurality of blind mate connectors 422 of the baseboard component are positioned to mate with the plurality of GPU module interface component blind mate connectors 430. In certain embodiments, the plurality of GPU module interface component blind mate connectors 430 includes respective PCIe type blind mate connectors. In certain embodiments, each GPU module interface component 432 includes a CEM type PCIe interface printed circuit board 434. In certain embodiments, the direct connect component connection system eliminates the need for point-to-point PCIe cables to connect a baseboard component with a GPU module array.

In certain embodiments, the direct connect component connection system is configured to allow the baseboard component to connect directly with the PCIe interface printed circuit boards of each of the plurality of GPU modules of the GPU module array. In certain embodiments, by connecting directly with the PCIe interface printed circuit boards, the baseboard component physically overlaps with a portion of the GPU module array. In certain embodiments, by so overlapping, the overall depth of the combination of the direct connect component connection system and the GPU module array is reduced.

Referring now to FIG. 4B, when servicing the GPU module array, the direct connect baseboard component is simply unplugged from the plurality of GPU module interface component blind mate connectors. In certain embodiments, by so unplugging the direct connect baseboard component, all of the GPU modules of the GPU module array are accessible for servicing. In certain embodiments, when servicing of the GPU module array is complete, the direct connect baseboard component is simply re-plugged into the plurality of GPU module interface component blind mate connectors. In certain embodiments, the direct connect baseboard component includes a lever mechanism to assist in plugging and unplugging the direct connect baseboard component to the plurality of GPU module interface component blind mate connectors.

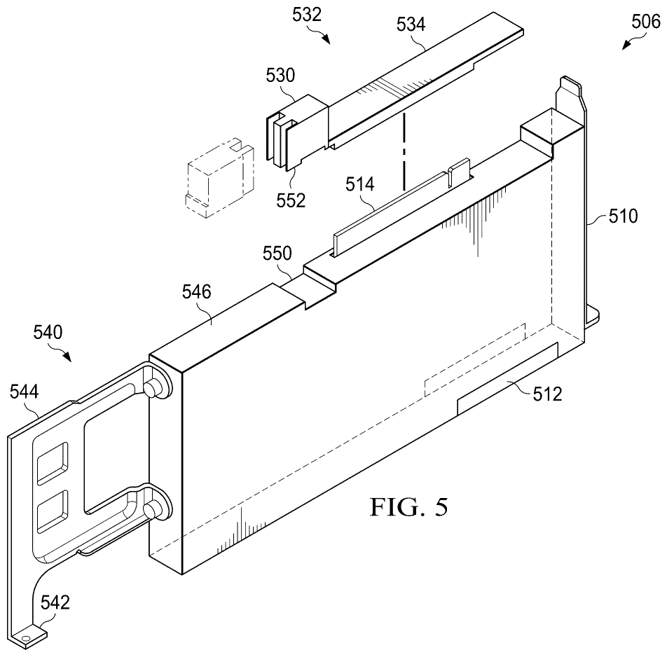

FIG. 5 shows a perspective view of a component 500 used with a component connection system. In certain embodiments, the component 500 includes a GPU module 510. In certain embodiments, the GPU module includes a CEM GPU module form factor. In certain embodiments, the GPU module 510 includes a GPU card edge 512, a PCIe card edge 514, or a combination thereof. In certain embodiments, the GPU card edge 512 is used when configuring a GPU module array with point-to-point GPU module to GPU module connections. In certain embodiments, the GPU card edge 512 conforms to a GPU interconnect specification. In certain embodiments, the GPU interconnect specification confirms to the VNLink interconnection specification, the UALink specification, or a combination thereof.

In certain embodiments, the component 500 includes a GPU module interface component blind mate connector 530. In certain embodiments, the GPU module interface component blind mate connector 530 is included within a GPU module interface component 532. In certain embodiments, a blind mate connector of a baseboard component is positioned to mate with the GPU module interface component blind mate connector 530 when the component 500 is included within a GPU module array. In certain embodiments, the GPU module interface component blind mate connector 530 includes a PCIe type blind mate connector. In certain embodiments, the GPU module interface component 532 includes a CEM type PCIe interface printed circuit board 534. In certain embodiments, the printed circuit board 534 connects with the PCIe card edge 514 of the GPU module 510.

In certain embodiments, the component 500 includes a mechanical support device 540. In certain embodiments, the mechanical support device 540 is attached to a rear edge of the GPU module 510. In certain embodiments, the mechanical support device 540 includes an attachment aperture 542, a support edge 544, or a combination thereof. In certain embodiments, the attachment aperture 540 facilitates attachment of the component 500 to a portion of an information handling system. In certain embodiments, the attachment aperture 540 facilitates attachment of the component 500 to a chassis, an array housing, or a combination thereof, of an information handling system. In certain embodiments, the support edge 544 provides structural support of an underside of a direct connect baseboard component. In certain embodiments, when the component is mounted as part of an array of components, the combination of support edges 544 provide lateral structural support of an underside of a direct connect baseboard component. In certain embodiments, the support edge 544 is substantially (i.e., +/−10%) horizontally on line with a top edge 546 of the component 500.

In certain embodiments, the GPU module 510 includes a recess 550. In certain embodiments, the GPU module interface component blind mate connector 530 includes an underside projection 552. In certain embodiments, when the GPU module interface component 532 is attached to the GPU module 510, the underside projection 552 fits within the recess 550 of the GPU module 510.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A direct connect component connection system for an information handling system, comprising:
a baseboard component, the baseboard component comprising a printed circuit board and a plurality of blind mate connectors positioned along an edge of the printed circuit board; and;
a plurality of component interface components, each of the plurality of component interface components comprising a respective component interface blind mate connector, each respective component interface blind mate connector being positioned to directly mate with a blind mate connector of the baseboard component.

2. The direct connect component connection system of claim 1, wherein:
the plurality of blind mate connectors comprises a plurality of peripheral component interconnect express (PCIe)type blind mate connectors; and,
each respective component interface blind mate connector comprises a PCIe type blind mate connector.

3. The direct connect component connection system of claim 2, wherein:
each of the plurality of component interface components comprises a respective PCIe interface component, the PCIe interface component providing a PCIe type interface between a component of the information handling system and the baseboard component.

4. The direct connect component connection system of claim 1, wherein:
each of the plurality of component interface components is associated with a respective component within an array of components.

5. The direct connect component connection system of claim 4, wherein:
each of the plurality of components of the array of components is configured to correspond to a card electromechanical (CEM) form factor.

6. The direct connect component connection system of claim 4, wherein:
each of the plurality of components of the array of components comprises a graphics processing unit (GPU) module.

7. A component array system for use in an information handling system comprising:
an array of components, the array of components comprising a plurality of components; and,
a direct connect component connection system for directly connecting with the array of components, the direct connect component connection system comprising:
a baseboard component, the baseboard component comprising a printed circuit board and a plurality of blind mate connectors positioned along an edge of the printed circuit board; and;
a plurality of component interface components, each of the plurality of component interface components comprising a respective component interface blind mate connector, each respective component interface blind mate connector being positioned to directly mate with a blind mate connector of the baseboard component.

8. The component array system of claim 7, wherein:
the plurality of blind mate connectors comprises a plurality of peripheral component interconnect express (PCIe)type blind mate connectors; and,
each respective component interface blind mate connector comprises a PCIe type blind mate connector.

9. The component array system of claim 8, wherein:
each of the plurality of component interface components comprises a respective PCIe interface component, the PCIe interface component providing a PCIe type interface between a component of the information handling system and the baseboard component.

10. The component array system of claim 7, wherein:
each of the plurality of component interface components is associated with a respective component within the array of components.

11. The component array system of claim 10, wherein:
each of the plurality of components of the array of components is configured to correspond to a card electromechanical (CEM) form factor.

12. The component array system of claim 11, wherein:
each of the plurality of components of the array of components comprises a graphics processing unit (GPU) module.

13. A system comprising:
a chassis;
a processor contained within the chassis;
a data bus coupled to the processor; and,
an array of components contained within the chassis, the array of components comprising a plurality of components; and,
a direct connect component connection system for directly connecting with the array of components, the direct connect component connection system comprising:
a baseboard component, the baseboard component comprising a printed circuit board and a plurality of blind mate connectors positioned along an edge of the printed circuit board; and;
a plurality of component interface components, each of the plurality of component interface components comprising a respective component interface blind mate connector, each respective component interface blind mate connector being positioned to directly mate with a blind mate connector of the baseboard component.

14. The system of claim 13, wherein:
the plurality of blind mate connectors comprises a plurality of peripheral component interconnect express (PCIe)type blind mate connectors; and,
each respective component interface blind mate connector comprises a PCIe type blind mate connector.

15. The system of claim 14, wherein:
each of the plurality of component interface components comprises a respective PCIe interface component, the PCIe interface component providing a PCIe type interface between a component of the information handling system and the baseboard component.

16. The system of claim 13, wherein:
each of the plurality of component interface components is associated with a respective component within the array of components.

17. The system of claim 16, wherein:
each of the plurality of components of the array of components is configured to correspond to a card electromechanical (CEM) form factor.

18. The system of claim 17, wherein:
each of the plurality of components of the array of components comprises a graphics processing unit (GPU) module.
